(19) United States
(12) Patent Application Publication
(10) Pub. No.: US 2011/0088759 A1
(43) Pub. Date: Apr. 21, 2011

(54) FULLERENE-CAPPED GROUP IV SEMICONDUCTOR NANOPARTICLES AND DEVICES MADE THEREFROM

(75) Inventors: Elena Rogojina, Los Altos, CA (US); David Jurbergs, Austin, TX (US)

(73) Assignee: Innovalight, Inc.

(21) Appl. No.: 12/976,215

(22) Filed: Dec. 22, 2010

Related U.S. Application Data
(63) Continuation of application No. 11/844,827, filed on Aug. 24, 2007, now abandoned.
(60) Provisional application No. 60/841,983, filed on Aug. 31, 2006.

(51) Int. Cl. H01L 31/028; C01B 31/30; C01B 31/36; H01B 1/02; H01B 1/04; H01B 1/12; B82Y 30/00

(52) U.S. Cl. 136/252; 423/439; 423/345; 252/520.1; 252/521.3; 252/519.3; 977/734; 977/740; 977/773

(57) ABSTRACT

Fullerene-capped Group IV nanoparticles, materials and devices made from the nanoparticles, and methods for making the nanoparticles are provided. The fullerene-capped Group IV nanoparticles have enhanced electron transporting properties and are well-suited for use in photovoltaic, electronics, and solid-state lighting applications.

### CROSS-REFERENCE TO RELATED APPLICATIONS

This application is a Continuation of U.S. application Ser. No. 11/844,827, filed Aug. 24, 2007, which claims the benefit of U.S. Provisional Patent Application Ser. No. 60/841,983, filed Aug. 31, 2006, the entire disclosures of which are incorporated by reference.

### FIELD OF THE INVENTION

What is disclosed herein generally relates to fullerene-capped Group IV semiconductor nanoparticles, to photoactive materials made from the fullerene-capped Group IV semiconductor nanoparticles, to methods for making the fullerene-capped Group IV semiconductor nanoparticles, and to devices incorporating such nanoparticles.

### BACKGROUND

Nanosized semiconductors, including silicon and germanium nanoparticles, are capable of absorbing solar radiation over a broad range of wavelengths and converting the solar radiation into free carriers in the form of electron/hole pairs. To generate electricity effectively, however, the electron/hole pairs created through the absorption of photons must be separated and extracted from the Group IV semiconductor nanoparticles.

Capping groups, generally used to protect Group IV semiconductor nanoparticle surfaces against oxidation, may facilitate the stabilization of the electronic and optical properties of Group IV semiconductor nanoparticles, resulting in improved performance of these materials in photovoltaic, electronic, and solid-state lighting applications. For example, silicon and germanium nanoparticles are typically treated with terminal alkenes or alkynes, as well as other moieties such as alcohols or thiols, to passivate their surfaces. (See J. Buriak, Chem. Rev., 2002, Vol. 102, 1271; M. H. Nayfeh, E. V. Rogozhina, and L. Mitas, “Silicon Nanoparticles: Next generation of Ultrasensitive Fluorescent Nano-Organic Markers,” in “Functionalization and Surface Treatment of Nanoparticles”, Baraton M.-I. Ed.: American Scientific Publishers: San Francisco, 2003, Ch. 10; and D. Wang, Y.-L. Chang, Z. Liu, H. Dai, J. Am. Chem. Soc. 2005, Vol. 127, 11871.)

Unfortunately, most of these groups have electrically insulating properties that are likely to have a negative impact on charge separation and transport of electrons from the semiconductor nanoparticles into a surrounding media or matrix. Even the shortest alkyl chains attached to the semiconductor nanoparticles may create an insulating barrier for charge extraction.

In contrast to most organic passivating agents, fullerene molecules have electron transporting (acceptor-type) properties and are often utilized in photovoltaic devices. In fact, fullerene has been used both as a single electroactive component and as a component of blends with electroactive polymers and small molecules. (See F. Yang, M. Shtein, S. R. Forrest, Nature Mat., 2005, Vol. 4, 37; S. R. Forrest, P. Peumans, U.S. Pat. No. 6,580,027 B2; H. Hoppe, N. S. Sariciftci, J. Mater. Res., 2004, Vol. 19, 1924; and R. A. J. Janssen, J. C. Hummelen, N. S. Sariciftci, MRS Bulletin, 2005, Vols. 30, 33.)

In previous studies, nanoparticles have been passivated with a C₆₀ fullerene by linking the fullerenes to the nanoparticles through binder molecules or coupling agents. (See M. R. Ayers, U.S. Pat. No. 6,277,766 B1.) However, in these studies the C₆₀ molecules were used as part of a porous insulating layer in microelectronic devices. In another study, C₆₀ molecules were grafted onto hydride-terminated silicon (100) wafers. (See W. Feng, B. Miller, Langmuir, 1999, Vol. 15, 3152 and J. Buriak, Chem.Rev., 2002, Vol. 102, 1271.) The substrate utilized in this study was bulk silicon, and as such, neither the surface nor groups attached to the surface play a significant role in influencing the properties of the resulting material.

Additionally, unlike bulk materials, for nanoparticles, the extraordinarily high surface area to volume ratios, as well as other factors, such as, for example, the bond strain between the Group IV atoms at curved surfaces, are conjectured to account for the unusual reactivity of the Group IV semiconductor nanoparticles. In that regard, given such reactivity, and given the impact of the nanoparticle surface in influencing properties of these materials, there is a need in the art for new methods providing synthetic modification of such reactive Group IV semiconductor nanoparticles, which in turn produce novel Group IV semiconductor nanoparticle compositions.

### SUMMARY

In some aspects of what is disclosed herein embodiments of fullerene-capped Group IV semiconductor nanoparticles, as well as embodiments of materials and devices made from the fullerene-capped Group IV semiconductor nanoparticles are provided. In other aspects of what is discloses, embodiments of methods for making the nanoparticles are provided. In the fullerene-capped Group IV semiconductor nanoparticles, the fullerene molecules are directly, covalently bound to the surface of the nanoparticles, provide enhanced electron transporting properties. As such, in still other aspects of what is disclosed, photovoltaic, electronic, and solid-state lighting applications enabled by the unique properties of the fullerene-capped Group IV semiconductor nanoparticles are provided.

The nanoparticles comprising a Group IV element may be, for example, silicon nanoparticles, germanium nanoparticles, tin nanoparticles, or nanoparticles made from alloys of silicon, tin and germanium. The Group IV semiconductor nanoparticles may have a core/shell structure. The fullerenes are directly, covalently bound to the surfaces of the nanoparticle, typically via an insertion reaction between an H-terminated surface of atom and a fullerene molecule, as will be discussed in more detail subsequently.

A plurality of the fullerene-capped nanoparticle may be used in a photoactive material which may be incorporated into a photoactive device, such as a photovoltaic cell.

Further objects, features and advantages of the invention will be apparent from the following detailed description when taken in conjunction with the accompanying drawings.

### BRIEF DESCRIPTION OF THE DRAWINGS

FIG. 1 depicts an embodiment of a fullerene-capped Group IV semiconductor nanoparticle.

FIG. 2 shows the absorption spectrum of an embodiment of fullerene-capped Group IV semiconductor nanoparticles.

### DETAILED DESCRIPTION

Since fullerenes have good electron transport, their use as capping groups on Group IV nanoparticles provides better electron transport than traditional organic capping groups. Thus, the direct, covalent attachment of electron-transporting fullerene molecules to the surfaces of nanoparticles results in better electronic wave function overlap, enhancing the charge separation and extraction of electrons from the Group IV semiconductor nanoparticles. The fullerene-capped Group IV semiconductor nanoparticles having enhanced electron transporting properties are well-suited for use in photovoltaic, electronic, and solid-state lighting applications.

As used herein, the term nanoparticle generally refers to structures having a diameter in at least one dimension (e.g., length, width or height) of no more than about 500 nm for some embodiments, between about 50 nm to about 200 nm for other embodiments and even between about 0.1 nm to about 10 nm for still other embodiments. For some embodiments, the Group IV semiconductor nanoparticles will have at least two and other embodiments, all three, dimensions of the nanoparticle will fall into the above-referenced size limitations. For some embodiments, the Group IV semiconductor nanoparticles will be small enough to exhibit quantum-confinement effects. For example, nanoparticles may have a maximum diameter in two or three dimensions of about 1 to 35 nm. The maximum diameter in two or three dimensions may also range from 1 to 20 nm or even from 1 to 10 nm. These smaller nanoparticles may exhibit a number of unique electronic, magnetic, catalytic, physical, optoelectronic and optical properties due to quantum confinement effects and surface energy effects. These quantum confinement effects may vary as the size of the nanoparticle is varied. In other cases, the nanoparticles will be larger. For example, the larger nanoparticles may have a diameter in at least one dimension of up to about 100 nm. Other nanoparticles may have a diameter in at least one dimension of up to about 200 nm or even up to about 500 nm. The nanoparticles within a given population of nanoparticles may include nanoparticles of different sizes.

The term nanoparticle also encompasses nano-scale particles having a wide variety of shapes. The nanoparticles may be generally spherical, as in the case of semiconductor nanocrystals, or elongated, as in the case of semiconductor nanowires or nanorods. In some instances the elongated nanoparticles will have an aspect ratio (i.e., the ratio of the length of the nanoparticle to the width of the nanoparticle) of at least 2, at least ten, at least 100, or even at least 1000. In other cases, the nanoparticles may take on more complex geometries, including branched geometries or shapes, such as cubic, pyramidal, double-square pyramidal, or cube-octahedral. The nanoparticles within a given population of nanoparticles may have a variety of shapes.

The semiconductor nanoparticles are made entirely, or partially, from at least one Group IV element. Suitable nanoparticles include, but are not limited to, silicon nanoparticles, germanium nanoparticles, tin nanoparticles, silicon-germanium alloy nanoparticles and nanoparticles comprising alloys of silicon, germanium, and tin. As previously mentioned, the Group IV semiconductor nanoparticles may be core/shell structures. By way of example, but not limited to, the core/shell nanoparticles may include a silicon core and a germanium shell, or a germanium shell and a silicon core.

Additionally, the nanoparticles may be single-crystalline, polycrystalline, or amorphous in nature. A plurality of nanoparticles may include nanoparticles of a single type of crystallinity or may consist of a range or mixture of crystallinity (i.e. some particles crystalline, others amorphous).

Methods for synthesizing semiconductor nanoparticles include plasma synthesis, laser pyrolysis, thermal pyrolysis, and wet chemical synthesis. Suitable methods for forming nanoparticles comprising Group IV semiconductors may be found in U.S. Pat. Nos. 4,994,107, 5,695,617, 5,850,064, 6,585,947, 6,855,204, 6,723,606, 6,586,785, U.S. Patent Application Publication Nos. 2004/0229447, 2006/0042414, 2006/0051505, and WO0114250, the entire disclosures of which are incorporated herein by reference.

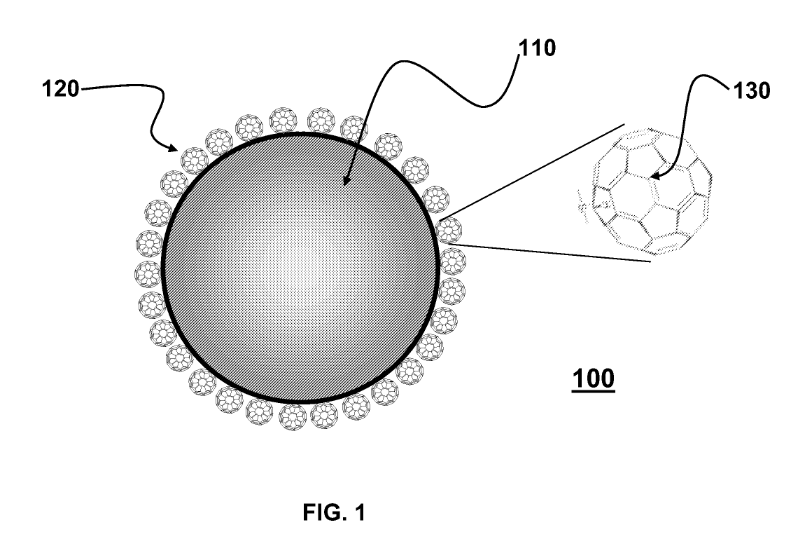

FIG. 1 depicts an embodiment of fullerene-capped Group IV semiconductor nanoparticles [100]. In FIG. 1, a cross-sectional area of a silicon nanoparticle [110] is shown capped with fullerenes [120] that are directly covalently bound to the surface of the silicon nanoparticle. The perspective is such that the silicon nanoparticle is about 10 nm [110]. The expanded view of the fullerene bonded to a surface silicon atom [130] shows clearly that the fullerene is directly bound to the surface through a fullerene-carbon-silicon-surface-atom bond. In the expanded view [130], it can also be seen that a fullerene is a cage like, hollow, carbon molecule composed of hexagonal and pentagonal groups of carbon atoms.

Some examples of suitable fullerenes include fullerenes having 60 carbon atoms (“C₆₀”), fullerenes having 70 carbon atoms (“C₇₀”), and the like, and derivatives thereof In some cases, the fullerenes may be functionalized. For other embodiments, C₇₆, C₈₄, C₉₀, C₉₆ fullerenes are contemplated for use in synthesizing fullerene-capped Group IV semiconductor nanoparticles. In still other embodiments, fullerenes to about 300 carbon atoms are considered. Useful properties may be additionally imparted to embodiments of fullerene-capped Group IV semiconductor nanoparticles by the use of endohedral fullerenes, which are fullerenes having atoms or molecular fragments within fullerene cages. Still other embodiments of fullerene-capped Group IV semiconductor nanoparticles may be synthesized using derivatives of fullerenes, such as PCBM (Phenyl C61 Butyric Acid Methyl Ester). Other examples of derivatized fullerenes include, but are not limited to, butryric acid methyl esters, hydroxylated fullerenes, carboxylated fullerenes, and fullerene hydrides.

As previously mentioned, the Group IV semiconductor nanoparticles are highly reactive. As such, care is taken to maintain the Group IV semiconductor nanoparticles in inert reaction conditions until stably capped with fullerene molecules. Disclosure of such methods for maintaining the Group IV semiconductor nanoparticles has been given in PCT application, “Stably Passivated Group IV Semiconductor Nanoparticles and Methods and Compositions Thereof” with filing date of 11 Aug. 2006, and application serial number [PCT/US2006/xxxxxx], the entirety of which is incorporated by reference.

Some embodiments of the methods of making the fullerene-capped nanoparticles are based on an insertion reaction of an hydrogen-terminated Group IV semiconductor nanoparticles with fullerene molecules. The reaction is an insertion reaction of a conjugated bond of the fullerene molecule with of a hydrogen-terminated Group IV atom on the surface of the Group IV semiconductor nanoparticle. This insertion reaction involves cleaving the bond between the hydrogen and the Group IV atom it is bonded to using thermal activation. Such thermal activation results in a homolytic cleavage of the Group IV atom-hydrogen bond to form surface Group IV atom radicals, which Group IV atom radicals in turn react with an available double bond of a fullerene molecule to form Group IV atom-carbon bonds. The carbon radical formed on the fullerene molecule, in turn reacts with hydrogen from nearby hydrogen-terminated Group IV atoms. The terms hydrosilylation, hydrogermylation and hydrostannylation are used to describe this kind of insertion reaction art hydrogen-terminated surface silicon atoms, hydrogen-terminated germanium atoms, and hydrogen-terminated tin atoms, respectively. The methods result in the covalent attachment of fullerene molecules to the surface of the nanoparticles without any intervening molecular groups. In some cases, the fullerenes may form a monolayer on the surface of the nanoparticles.

Additionally, other reactions are known for creating Group IV semiconductor-carbon bonds. Descriptions of protocols for the above described insertion reaction, and other known reactions for forming Group IV semiconductor element-carbon bonds may be found in J. M. Buriak, Chem. Rev., vol. 102, pp. 1271-1308 (2002), the entire disclosure of which is incorporated herein by reference.

A plurality of the fullerene-capped nanoparticles may be used in a photoactive material (e.g. a material capable of converting. solar radiation into electrical current). Within the photoactive material, the fullerene capped Group IV semiconductor nanoparticles may be in the form of a neat mixture, or they may be dispersed in an inorganic or polymer matrix or binder. The polymer may be, but is not necessarily, an electrically conductive polymer. Many suitable electrically conductive polymers are known and commercially available. These include, but are not limited to, conjugated polymers such as polythiophenes, poly(phenyl vinylene) (PPV), polyanilene, polyfluorene. Other suitable conjugated polymers that may be used as a matrix in the photoactive materials are described in U.S. Patent Application Publication No. 2003/0226498, the entire disclosure of which is incorporated herein by reference.

Within the photoactive material, any elongated nanoparticles, may be oriented randomly, or may be oriented non-randomly with a primary alignment direction perpendicular to the surface of the material. A population of elongated nanoparticles is “non-randomly oriented with a primary alignment direction perpendicular to the surface of the material” if significantly more (e.g., ≧5% or ≧10% more) of the elongated nanoparticles are aligned in a perpendicular orientation than would be in a completely random distribution of nanoparticles.

Generally, the photoactive material has a fullerene-capped Group IV semiconductor nanoparticle content that is sufficiently high to allow the material to conduct the electrons and holes generated when the material is exposed to light. Thus, the desired nanoparticle loading will depend on the sensitivity and/or efficiency requirements for the particular application and on the composition of the nanoparticles in the photoactive material.

The Group IV semiconductor nanoparticles within the photoactive materials may have a polydisperse or a substantially monodisperse size distribution, where particle diameter is the attribute measured, which diameter of a nanoparticle is the largest cross-sectional diameter of the nanoparticle. In applications where high nanoparticle loading is desirable, it may be advantageous to use nanoparticles with a polydisperse size distribution, which allows for denser packing of the nanoparticles. As used herein, the term “substantially monodisperse” refers to a plurality of nanoparticles which deviate by less than 20% root-mean-square (rms) in diameter in some embodiments, less than 10% rms in other embodiments, and less than 5% rms in still other embodiments. The term polydisperse refers to a plurality of nanoparticles having a size distribution that is broader than monodisperse. For example, a plurality of nanoparticles which deviate by at least 25%, 30%, or 35%, root-mean-square (rms) in diameter would constitute a polydisperse collection of nanoparticles. One advantage of using a population of Group IV nanoparticles having a polydisperse size distribution is that different nanoparticles in the population will be capable of absorbing light of different wavelengths, which may be a desirable property in applications, such as photovoltaic cells.

In addition to, or as an alternative to, tuning the absorption characteristics of the photoactive material by using nanoparticles of different sizes, the absorption characteristics of the photoactive material may be tuned by using nanoparticles having different chemical compositions. For example, the active layer can include a blend of silicon, germanium, and tin Group IV semiconductor nanoparticles.

Multiple films of the photoactive material may be applied over a substrate to form a photoactive material having the desired thickness. In some embodiments the compositions and/or size distributions of the nanoparticles in the various film layers may be different, such that different layers have different light absorbing characteristics. For example, the layers may be arranged with an ordered distribution, such that the nanoparticles having the highest bandgaps are near one surface of a multilayered photoactive material and the nanoparticles having the lowest bandgaps are near the opposing surface of a multilayered photoactive material.

The photoactive materials may be used in a variety of devices which convert electromagnetic radiation into an electric signal. Such devices include photovoltaic cells, photoconverters, and photodetectors. Generally, these devices will include the photoactive material electrically coupled to two or more electrodes. Other layers commonly employed in photoactive devices (e.g., barrier layers, blocking layers, recombination layers, insulating layers, protective casings, etc.) may also be incorporated into the devices. Each layer in the device may be quite thin, e.g., having a thickness of no more than about 5.0 micron, no more than about 1.0 micron, or even no more than about 500 nm. However, layers having greater thicknesses may also be employed. When the photoactive material is used in a photovoltaic cell, the device may further include a power consuming device, or load, (e.g., a lamp, a computer, etc.) which is in electrical communication with, and powered by, one or more photovoltaic cells. When the photoactive material is used in a photoconductor or photodetector, the device further includes a current detector coupled to the photoactive material.

A photovoltaic device may be fabricated from the photoactive materials as follows. A substrate with a bottom transparent electrode (e.g., ITO on a polymer film or glass) is cleaned and a thin buffer layer (e.g., about 30-100 nm) of PEDOT:PSS is spin-coated onto the electrode. Organic or inorganic buffer layers other than PEDOT:PSS may also be used, including buffer layers that help to planarize the substrate surface and/or prepare the substrate surface for optimization of charge extraction during the operation of the photovoltaic device. A photoactive active layer comprising a plurality of the capped nanoparticles is formed over the PEDOT:PSS by spin coating a solution of the capped nanoparticles in a solvent (e.g., in chloroform). (Other suitable methods for forming the photoactive layer include, but are not limited to, plasma deposition, spray coating, and ink jet or screen printing.) Finally, a top electrode (e.g., a 200 nm aluminum layer) is deposited over the photoactive layer.

### EXAMPLES

The examples given below are non-limiting examples of methods that may be used to produce fullerene-capped Group IV semiconductor nanoparticles. In theses examples, the Group IV semiconductor nanoparticles were silicon and germanium nanocrystals.

Silicon nanocrystals about 9 nm in diameter were produced using a radiofrequency plasma method and apparatus substantially as described in U.S. patent application Ser. No. 11/155,340. In this method the silicon nanocrystals were produced in a plasma environment, collected on a mesh polyethylene bag and held under an inert gas atmosphere that was substantially oxygen-free. Without exposing the silicon nanocrystals to air, the bag with the nanocrystals was isolated in a container between two ball valves and transferred under a substantially oxygen-free atmosphere into a nitrogen glove box. All of the subsequent reaction steps were done in the glove box under inert conditions. About 60 mg of the silicon nanocrystals was weighed out in glass beaker and dispersed in 30 ml of degassed mesitylene solvent. The resulting slurry of nanocrystals was transferred into a glass flask, and approximately 0.1 g of fullerene powder was added to the flask. The slurry was heated to the boiling point of mesitylene with vigorous stirring for 5 days.

After the reaction was completed, the reaction solution could be removed from the inert conditions, and be further processed. At this point, the silicon nanocrystal powder was not apparent through the predominant black color imparted to the solution by the unreacted fullerene. The heating was stopped, mesitylene removed under vacuum, and a dark brown residue was dissolved in about 100 ml of chlorobenzene. This chlorobenzene solution obtained was filtered through paper filter (1-5 μm pore size).

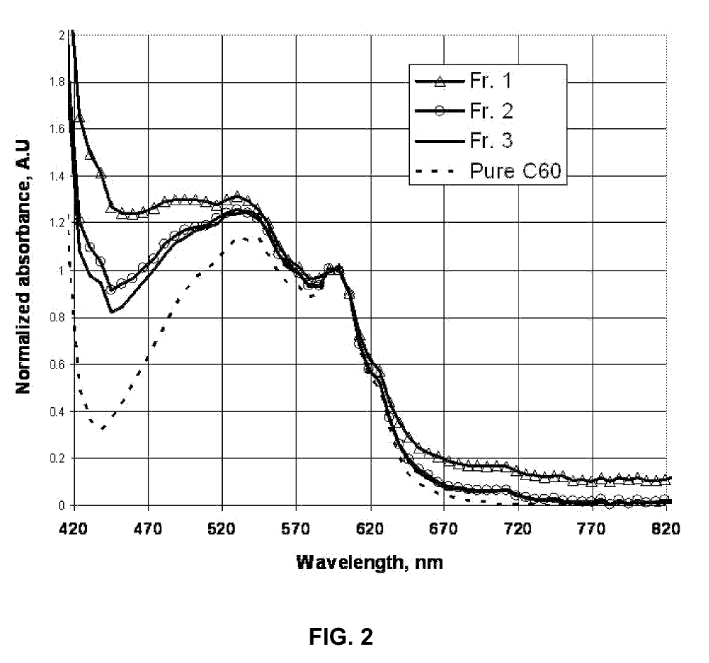

The filtrate was purified further via selective precipitation using methanol as anti-solvent. To 100 ml of the filtrate, 50 ml of methanol was added, which produced a brown, cloudy solution, which was subsequently filtered through a 0.45 micron filter. The material remaining on the filter was collected as Fraction 1. The process was repeated on the remaining filtrates twice again, producing Fraction 2, and Fraction 3. The enriched fractions of the fullerene-capped silicon nanocrystals so obtained were characterized with absorbance measurements, as shown in FIG. 2.

In FIG. 2, the absorbance spectra in the visible region of the electromagnetic spectrum from 420 nm to 820 nm is shown for the three enriched fractions prepared as described above in comparison to a sample of the fullerene starting material. As can be seen in comparison, the spectra of the enriched fractions of the fullerene-capped silicon nanocrystals have features not seen in the fullerene starting material. Specifically, between about 470 nm and 570 nm, there are two shoulders present, in addition to a shoulder at about 700 nm that are not part of the signature of the fullerene starting material. Moreover, not only are there features that are unique to the fullerene-capped silicon nanoparticles, but there are features appearing in the silicon nanocrystal product that can be attributed to fullerene; specifically, but not limited to, the prominent shoulder between 570 nm and 620 nm.

Germanium nanocrystals of about 5 nm in diameter were produced as described in above in the example given for silicon. As was described for the reaction of the silicon nanocrystals in the above example, all of the reaction steps for this example of fullerene-capped germanium nanocrystals were done in the glove box under inert conditions. In the glove box, about 400 mg of the germanium nanocrystals were weighed out in glass beaker and dispersed in 40 ml of degassed chlorobenzene solvent. The resulting slurry of nanocrystals was transferred into a glass flask, still in the glove box, and 0.33 g of fullerene as a powder was added to the flask. The slurry was heated to the boiling point of chlorobenzene, sealed inside of glove box and heated outside with vigorous stirring for 2.5 months. At this point, heating was stopped, solution was filtered through 0.22 μm Teflon membrane and solvent was removed with rotor evaporator. To remove unreacted fullerene from the sample sublimation for 7 h at 400 ° C. and residual pressure of 10⁻⁵ Torr was done. The residue at the bottom of sublimation flask was characterized with absorbance measurements, which were similar in nature to those shown in FIG. 3, verifying that the purified material was substantially different from the reactants.

For the purposes of this disclosure and unless otherwise specified, “a” or “an” means “one or more.” All patents, applications, references and publications cited herein are incorporated by reference in their entirety to the same extent as if they were individually incorporated by reference.

While the principles of this invention have been described in connection with exemplary embodiments, it should be understood clearly that these descriptions are made only by way of example and are not intended to limit the scope of the invention. What has been disclosed herein has been provided for the purposes of illustration and description. It is not intended to be exhaustive or to limit what is disclosed to the precise forms described. Many modifications and variations will be apparent to the practitioner skilled in the art. What is disclosed was chosen and described in order to best explain the principles and practical application of the disclosed embodiments of the art described, thereby enabling others skilled in the art to understand the various embodiments and various modifications that are suited to the particular use contemplated. It is intended that the scope of what is disclosed be defined by the following claims and their equivalence.

What is claimed is:

1. A fullerene-capped Group IV semiconductor nanoparticle created by the method comprising:
dispersing a set of Group IV semiconductor nanoparticles and a set of fullerenes in a solution, wherein each nanoparticle of the set of Group IV semiconductor nanoparticles includes a surface hydrogen bond;
thermally activating the surface hydrogen bond;
cleaving the surface hydrogen bond on at least one nanoparticle of the set of Group IV semiconductor nanoparticles to create a Group IV atom radical;
wherein at least one fullerene of the set of fullerenes reacts with the Group IV atom radical to form a Group IV atom—carbon bond.

2. The fullerene-capped Group IV semiconductor nanoparticle of claim 1, wherein the nanoparticle comprises silicon.

3. The fullerene-capped Group IV semiconductor nanoparticle of claim 1, wherein the nanoparticle is a germanium nanoparticle.

4. The fullerene-capped Group IV semiconductor nanoparticle of claim 1, wherein the nanoparticle comprises tin.

5. The fullerene-capped Group IV semiconductor nanoparticle of claim 1, wherein the nanoparticle comprises an alloy including at least two elements selected from a group consisting of silicon, germanium and tin.

6. The fullerene-capped Group IV semiconductor nanoparticle of claim 1, wherein the nanoparticle comprises a core region and a shell region, wherein at least one of the core region and the shell region comprises a Group IV element.

7. The fullerene-capped Group IV semiconductor nanoparticle of claim 1, wherein the set of fullerenes is selected from the group consisting of C₆₀, C₇₀, C₇₆, C₈₄, C₉₀, and C₉₆.

8. A photoactive material comprising a plurality of nanoparticles, wherein each nanoparticle of the plurality of nanoparticles is formed from at least one Group IV semiconductor element, and is further reacted with a fullerene.

9. The photoactive material of claim 8, further comprising an organic or inorganic matrix in which the plurality of nanoparticles is embedded.

10. The photoactive material of claim 9, wherein the photoactive material is configured to be in electrical communication with two electrodes.

11. The photoactive material of claim 10, wherein the photoactive material forms a photovoltaic cell.

12. A method of generating an electric current, comprising:
forming a set of nanoparticles from at least one Group IV semiconductor element;
reacting the set of nanoparticles with a set of fullerenes;
forming a film including the set of nanoparticles and the set of fullerenes;
applying the film to a substrate;
coupling the film to a set of electrodes; and
exposing the film to solar radiation.

13. A method for producing a fullerene-capped Group IV semiconductor nanoparticle, comprising;
dispersing a set of Group IV semiconductor nanoparticles and a set of fullerenes in a solution, wherein each nanoparticle of the set of Group IV semiconductor nanoparticles includes a surface hydrogen bond;
thermally activating the surface hydrogen bond;
cleaving the surface hydrogen bond on at least one nanoparticle of the set of Group IV semiconductor nanoparticles to create a Group IV atom radical;
wherein at least one fullerene of the set of fullerenes reacts with the Group IV atom radical to form a Group IV atom—carbon bond.

14. The method of claim 13, wherein the nanoparticle includes silicon.

15. The method of claim 13, wherein the nanoparticle includes germanium.

16. The method of claim 13, wherein the nanoparticle includes tin.

17. The method of claim 13, wherein the nanoparticle comprises an alloy of at least two elements selected from a group consisting of silicon, germanium and tin.

18. The method of claims 13, wherein the nanoparticle is a nanowire.

19. The method of claim 13, wherein the nanoparticle comprises a core region and a shell region, wherein at least one of the core region and the shell region comprises a Group IV element.

20. The method of claim 13, wherein the set of fullerenes is selected from the group consisting of C₆₀ and C₇₀.
